(19) United States
(12) Patent Application Publication
(10) Pub. No.: US 2006/0102385 A1
(43) Pub. Date: May 18, 2006

(54) Printed board for electronic devices controlling a motor vehicle

(76) Inventors: Andreas Heise, Erzhausen (DE); Jochen Beuss, Erzhausen (DE); Roberto Schlenker, Ingolstadt (DE); Philipp Herbst, Neufahrn (DE)

Correspondence Address: Gerlinde Nattler;Continental Teves Inc, One Continental Drive, Auburn Hills, MI, 48326, US

(21) Appl. No.: 10/517,948

(22) PCT Filed: Jun. 14, 2003
(86) PCT No.: PCT/EP03/06293

§ 371 Date: Sep. 26, 2005

(30) Foreign Application Priority Data
Jun. 21, 2002 (DE) 102 27 903.9

(51) Int. Cl. H05K 1/09; H01H 85/04

(52) U.S. Cl. 174/257; 337/159

(57) ABSTRACT

In order to protect a printed circuit board (1, 1′) especially against the development of heat by simple means, said printed circuit board includes strip conductors for electronic circuits and connections for a voltage supply unit equipped with at least one SMD-component and additional electronic and/or electromechanical parts that are soldered in a suitable manner. The voltage supply unit is connected to one or several supplying strip conductors (2). At least one of the supplying strip conductors (2) includes a break to this end which is bridged in a conductive manner by means of a fuse bridge (6), said fuse bridge (6) containing or being made of a basic material, the melting point of which is lower than the melting point of the material of which the strip conductors are made.

### BACKGROUND OF THE INVENTION

The present invention relates to a printed circuit board comprising strip conductors for electronic circuits and connections for a voltage supply unit being equipped with at least one SMD-component and additional electronic and/or electromechanical parts that are soldered in a suitable manner, said voltage supply unit being connected to one or several supplying strip conductors. The invention also relates to a method of manufacturing a printed circuit board of this type.

Printed circuit boards of this type can be provided especially for use in electronic control devices, for example in driving dynamics controllers or ABS controllers. Should there be any defects caused by components or manufacture in the circuit fitted to such printed circuit boards, the allowable printed circuit board temperature could be exceeded locally. The result could be, in turn, defects in further circuit components or even an additional heating up of circuit components due to an increased power loss that might have as a consequence the failure of individual circuit components or even overall assemblies.

### SUMMARY OF THE INVENTION

In view of the above, an object of the invention is to devise a printed circuit board of the above-mentioned type wherein unwanted additional heating up is reliably prevented even if component-related defects occur. Another objective is to provide a method of manufacturing a printed circuit board of this type. With respect to the printed circuit board, this object is achieved by the invention in that at least one of the supplying strip conductors includes a break which is bridged in a conductive manner by means of a fuse bridge, said fuse bridge containing or being made of a basic material, the melting point of which is lower than the melting point of the material of which the strip conductors are made.

The invention is based on the idea that causes of a possible overheating should be purposefully combated in order to provide an assembly that is especially guarded against component defects. Local overheating may e.g. occur when an electronic component causes development of excessive local heat due to a defect. This local heat development can cause unsoldering of the component in some cases. If such a component on the printed circuit board causes short circuits in voltage-conducting, especially wide strip conductor areas, the development of heat may indeed lead to more serious component damages due to the high current flowing. To effectively prevent such an occurrence, the printed circuit board should be protected against the supply of heat acting from any sources whatsoever. To this end, the printed circuit board is furnished with special elements, which in contrast to safety fuses reliably prevent further current supply to the printed circuit board and, thus, the potential occurrence of additional heat sources, rather due to locally developing temperature increases instead of due to locally developing current densities.

To ensure such a break of the voltage supply, being in conformity with demand, in the way of a passive, self-acting system without active influences from outside, the printed circuit board includes bridged breaks in the way of predetermined breaking points in the area of the supplying strip conductors, said breaks being rated for a purposeful melting off in a case of fire in the way of a thermal reaction to the heat emitted in a fire. The melting point of the basic material forming the fuse bridges is chosen appropriately to comply with this demand.

The circuit carriers can be simple printed circuit boards or boards with several wiring levels such as double, quadruple or multi layers.

When the printed circuit board is equipped with so-called ‘Surface Mounted Devices’, also referred to as SMD-components, (e.g. soldering paste printing with subsequent placement of the SMD-components and subsequent soldering), a fuse bridge of this type can be inserted in a purposely inset break in the supplying strip conductor. Preferably, the fuse bridge can be arranged close to the supply voltage connection (e.g. connector plug). The fuse bridge is favorably a solid piece of a material having a higher melting point, in particular a suitable solder, or any appropriately designed soldering material area, with the solder having approximately the same melting point as the used solder or, in the last mentioned case, consisting of the same material as the solder in particular.

To achieve particularly low manufacturing efforts with regard to the printed circuit board, the fuse bridges are favorably designed to allow mounting by the use of conventional soldering methods. To this end, the material of the fuse bridge is preferred to have a melting point higher than the melting point of the solder used for fastening the components. As a result, the fuse bridge will favorably not be melted open during the soldering process. This way the fuse bridge can be secured at corresponding locations in the area of the break in the strip conductor also by way of the solder during the conventional soldering process.

To safeguard a sufficiently high rate of conductivity of the fuse bridges in the normal operating condition, the respective fuse bridge advantageously is completely composed of metallic material, preferably of tin or tin alloy. Further, in order to ensure an electric contact with the strip conductors of a sufficiently high quality, the respective fuse bridge is conductively connected to the material of the strip conductor by means of the solder used in a soldering process in another or alternative favorable embodiment.

To be able to resort to conventional and low-cost placement concepts for achieving a particularly low manufacturing effort in the production of the printed circuit boards, the fuse bridge is favorably configured such that it can be employed in an automated pick-and-place process. To this end, the fuse bridge is favorably shaped in such a manner that it can be fed to a conventional pick-and-place machine in a taped and magazined fashion like per se known SMD-components.

A particularly simple construction of the fuse bridge can be reached by favorably manufacturing it by severing from a wire or a sheet-metal strip.

Particularly favorable electric conductivities of the fuse bridge and in particular an especially favorable solderability by using conventional soldering materials can be achieved by advantageously coating the basic material for manufacturing the fuse bridge with a layer, in particular made of tin, tin alloy, gold, or passivated copper.

The above-mentioned object is achieved with regard to the manufacture of the printed circuit board by manufacturing the fuse bridges immediately prior to equipping the printed circuit board, preferably by way of severing from a wire or a sheet-metal strip. This ensures the provision of the necessary fuse bridges in a particularly simple fashion directly when equipping the printed circuit board in conformity with demand and adapted to the situation.

The advantages achieved by the invention involve in particular that the fuse bridges will effectively prevent overheating of the printed circuit board. In addition, an appropriate layout of the printed circuit board allows achieving that the heat will always spread in the direction of the fuse bridge. When the heat reaches the area of the fuse bridge, the melting point of the bridge material is usually exceeded and, thus, current supply is effectively interrupted. The resultant interruption of the current flow will stop the heating up. Thus, the printed circuit board is equipped with a thermal fuse which, different from conventional fuses, will withstand even increased current intensities or densities over defined periods of time and interrupt the current flow as a reaction to temperatures higher than a predetermined limit temperature.

An embodiment of the invention will be explained in detail by way of the accompanying drawing.

### BRIEF DESCRIPTION OF THE DRAWINGS

In the drawing,

FIG. 1 is a printed circuit board comprising a number of strip conductors.

FIG. 2 is an alternative embodiment of a printed circuit board.

### DETAILED DESCRIPTION OF THE DRAWINGS

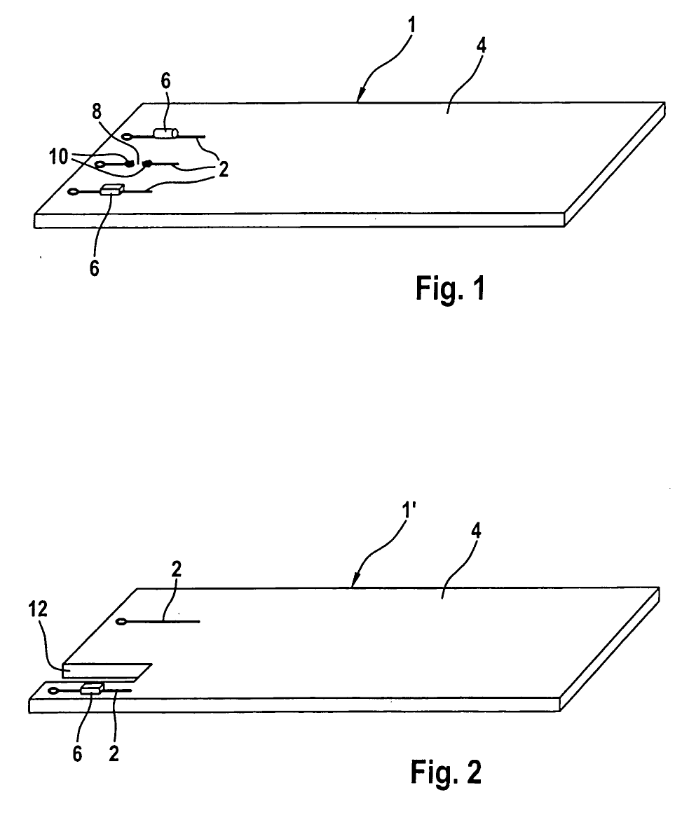

The printed circuit board 1 represented in FIG. 1 is intended especially for use in electronic control devices such as driving dynamics controllers, ABS controllers, or other vehicle control devices. To this end, the printed circuit board 1 is equipped with a number of SMD-components (not shown) and additional electronic and/or electromechanical components, which are mounted to the printed circuit board 1 by using an appropriate solder and are interconnected in an electrically appropriate fashion by way of a large number of strip conductors (not shown). In this arrangement, the printed circuit board 1 can be configured as a simple printed circuit board or even as a printed circuit board with several wiring levels such as double, quadruple, or multiple layers. To feed the active components with voltage and/or current, the printed circuit board 1 additionally includes a number of supplying strip conductors 2 which have an appropriate configuration especially for connecting an external voltage supply. In view of this purpose of application, the supplying strip conductors 2 are appropriately chosen especially in terms of their material and their dimensioning.

The printed circuit board 1 is configured to ensure a particularly high rate of operating safety even when component-induced defects occur. It is for this purpose planned to specifically suppress the spreading of locally fed heat on the surface of the printed circuit board 1.

To this end, the supplying strip conductors 2 are furnished with breaks or gaps respectively bridged by an associated fuse bridge 6. Fuse bridges 6, which can e.g. be configured like a cylinder or square as shown in the embodiment, are formed of electrically conductive material, in particular metal, and the melting point of its basic material is chosen to be lower than the melting point of the material that forms the supplying strip conductors 2. Thus, the development of heat in a locally damaged component will cause the respective fuse bridge 6 to melt thoroughly prior to further damage of the supplying strip conductors 2 or other strip conductors so that the electric contact is interrupted across the respective break or gap. Hence, the interruption of the current or voltage supply takes place automatically in the vicinity of a component so that heating up will no more be furthered by electric energy supplied. An example of such an interrupted voltage or current supply is illustrated for the medium of the supplying strip conductors 2 shown, depicting blowpipe beads 10 made up of the rests of the originally existing fuse bridge that are illustrated on both sides of the gap 8 which developed.

In addition, the fuse bridges 6 are configured such that the melting point of their basic material is higher than the melting point of the solder used for the equipment of the printed circuit board 1. It is thus ensured that it is possible to attach the fuse bridges 6 to the printed circuit board 1 even by using conventional placement methods and by using conventional soldering processes. The fuse bridges 6 are connected to the material of the respectively associated supplying strip conductor 2 by way of the solder used in the soldering process. The fuse bridges 6 can be manufactured especially by severing from a wire or a sheet-metal strip.

To ensure a particularly good processability of the fuse bridges 6 especially in connection with the soldering process used during placement of the printed circuit board 1, the basic material of the respective fuse bridge 6 is coated with a layer furthering the solderability, in particular made of tin, tin alloy, gold, or passivated copper.

In order to effectively prevent a cross-talk of local heat from one supplying strip conductor 2 to an adjacent supplying strip conductor 2 in addition, the printed circuit board 1′ illustrated in the embodiment of FIG. 2 includes a number of recesses 12, only one of which is shown in FIG. 2. The recesses 12 separate adjacent supplying strip conductors 2 from each other so that the skipping of local fires is at least impaired due to the reduced heat conductivity in the direction between the supplying strip conductors 2. Besides, a purposeful positioning of recesses 12 of this type renders it possible to canalize and align the heat conduction and dissipation in the basic member 4 of the printed circuit board 1′ in such a fashion that a purposeful introduction of heat into the area of the fuse bridge 6 shown in FIG. 2 takes place even if a component defect occurs in a laterally remote area of the printed circuit board 1′. Thus, premature failure of the fuse bridge 6 can be prevented due to the purposeful introduction of heat even in the event of fires that develop laterally remotely so that a reliable interruption of the current or voltage supply in the type of a passive system is ensured even for remote fires.

### LIST OF REFERENCE NUMERALS

1, 1′ printed circuit board
2 supplying strip conductors
4 basic member
6 fuse bridge
8 gap
10 blowpipe beads
12 recess

1.-10. (canceled)

11. A printed circuit board (1, 1′) comprising strip conductors for electronic circuits and connections for a voltage supply unit being equipped with at least one SMD-component and additional parts that are soldered in a suitable manner, said voltage supply unit being connected to at least one supplying strip conductor (2),
wherein at least one of the supplying strip conductors (2) includes a break which is bridged in a conductive manner by means of a fuse bridge (6), said fuse bridge (6) comprising a basic material, the melting point of which is lower than the melting point of the material of which the strip conductors are made.

12. The printed circuit board (1, 1′) as claimed in claim 11,
wherein the melting point of the basic material is at least as high as the melting point of the solder used for placement of the printed circuit board (1).

13. The printed circuit board (1, 1′) as claimed in claim 11,
wherein the fuse bridge (6) fully consists of metallic material.

14. The printed circuit board (1, 1′) as claimed in claim 13,
wherein the metallic material comprises tin or any tin alloy.

15. The printed circuit board (1, 1′) as claimed in claim 11,
wherein the fuse bridge (6) is connected to material of the strip conductor in a conductive fashion by means of the solder used in the soldering process.

16. The printed circuit board (1, 1′) as claimed in claim 11,
wherein the fuse bridge (6) is shaped in such a way that it can be fed to a conventional pick-and-place machine in a taped and magazined fashion like a per se known SMD-component.

17. The printed circuit board (1, 1′) as claimed in claim 11,
wherein the fuse bridge (6) is manufactured by severing from a wire or a sheet-metal strip.

18. The printed circuit board (1, 1′) as claimed in claim 11,
wherein the basic material for manufacturing the fuse bridge (6) is coated with a layer made of a material out of the group consisting of tin, any tin alloy, gold, and passivated copper.

19. The printed circuit board (1, 1′) as claimed in claim 11,
wherein adjacent supplying strip conductors (2) are separated from each other by recesses (12).

20. A method of manufacturing a printed circuit board (1, 1′) comprising strip conductors for electronic circuits and connections for a voltage supply unit being equipped with at least one SMD-component and additional electronic and/or electromechanical parts that are soldered in a suitable manner, said voltage supply unit being connected to at least one supplying strip conductor (2),
wherein at least one of the supplying strip conductors (2) includes a break which is bridged in a conductive manner by means of a fuse bridge (6), said fuse bridge (6) comprising a basic material, the melting point of which is lower than the melting point of the material of which the strip conductors are made.
the method comprising the step of manufacturing the fuse bridge (6) immediately prior to placement of the printed circuit board (1, 1′).
